(19) United States
(12) Patent Application Publication
(10) Pub. No.: US 2004/0230853 A1
(43) Pub. Date: Nov. 18, 2004

(54) Data processor and method for notification

(75) Inventor: Yoshio Miyamoto, Yokohama (JP)

Correspondence Address: McDermott, Will & Emery, 600 13th Street, N.W., Washington, DC, 20005-3096, US

(73) Assignee: Hitachi, Ltd.

(21) Appl. No.: 10/792,749

(22) Filed: Mar. 5, 2004

(30) Foreign Application Priority Data
May 15, 2003 (JP) 2003-136688

(51) Int. Cl. G06F 11/30; G06F 1/30; G06F 1/28; G06F 1/26; H03B 1/00; H03K 3/00

(52) U.S. Cl. 713/340; 713/300

(57) ABSTRACT

The data processing device has a battery, a memory, a detector and an message output. The memory stores data on electric power consumption or electric current. The detector detects electric power or electric current supplied from the battery. The message output indicates when the detected electric power or electric current supplied from the battery is greater than the data value read out from the memory.

### TECHNICAL FIELD

The present subject matter relates to a data processor such as a personal computer and a PDA (personal digital assistant) and a technique for notifying a user of a data processor.

### BACKGROUND

JP-A-2001-176562 discloses portable equipment holding a model of power consumption with the time and the day of the week as parameters. This equipment estimates the time when the battery power will run out depending upon the condition of use by the user, and produces an alarm, as required.

The consumption of electric current may increase more than expected first due to an increase in the memory and the addition of softwares. In such cases, equipment described in the above patent literature indicates estimated times as usual despite the remaining amount of the battery power is becoming small. Therefore, the user overlooks that the usable time is really becoming shorter than before.

For example, the user may use the data processing unit for his business. He may confirm the remaining amount of the battery power before taking holidays and consider the battery power will last sufficiently until the end of the holidays based on his past experience, and may, hence, leave the data processing unit without being electrically charged. If the battery power has been worn out, the user may find that the battery power has been discharged when he attempts to use the data processing unit after the holidays and get into a trouble in that the data processing unit cannot be readily used. When the data processing apparatus employs a DRAM (dynamic random access memory) as a memory for recording the data written by the user, the user may lose important data if the battery power is depleted.

There is a need for an improved data processor capable of suitably informing the user of the remaining amount of the battery power and the necessity of electric charging.

### SUMMARY

The concepts disclosed herein alleviate one or more of the above noted problems with power monitoring and/or notification of a user of a data processing device.

The data processing device has a battery, a memory, a detector and an message output. The memory stores data on electric power consumption or electric current. The detector detects electric power or electric current supplied from the battery. The message output indicates when the detected electric power or electric current supplied from the battery is greater than a data value read out from the memory.

### BRIEF DESCRIPTION OF THE DRAWINGS

FIG. 1 is a block diagram of a circuit of a data processor;

FIG. 2 is a flowchart illustrating a processing for measuring, comparing and informing the user as to the consumption of current;

FIG. 3 is a diagram of a database of current values for comparison;

FIG. 4 is a diagram of an alarm display; and

FIG. 5 is a flowchart illustrating a processing for measuring, comparing and informing the user as to consumption of current when the power source is turned off.

### DETAILED DESCRIPTION

Described below is an example of a data processor such as a laptop or handheld personal computer, a PDA or a cell phone.

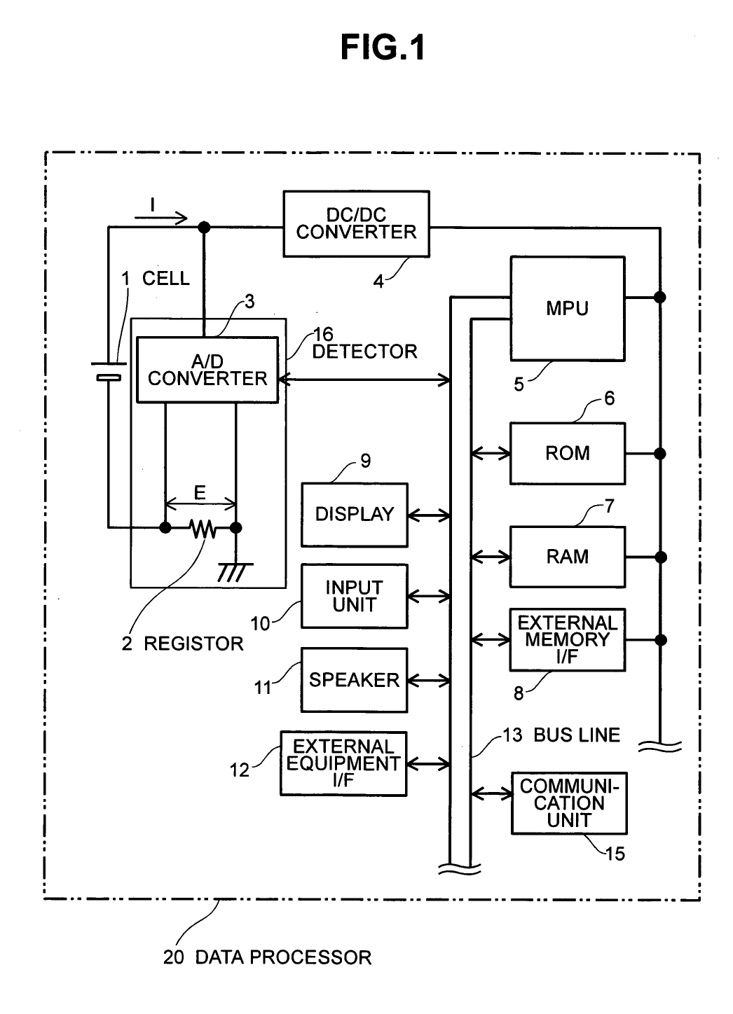

FIG. 1 is a block diagram of a circuit of the data processing unit. First, described below are constituent elements of the data processor 20.

An MPU (microprocessing unit) 5 controls the whole data processor 20. A ROM (read-only memory) 6 stores the programs and control data necessary for operating the MPU 5. A RAM (random access memory) 7 is a rewritable memory for temporarily storing the data handled by the MPU 5 at the time of executing the program and for storing the user data. An example of the RAM 7 may be a DRAM.

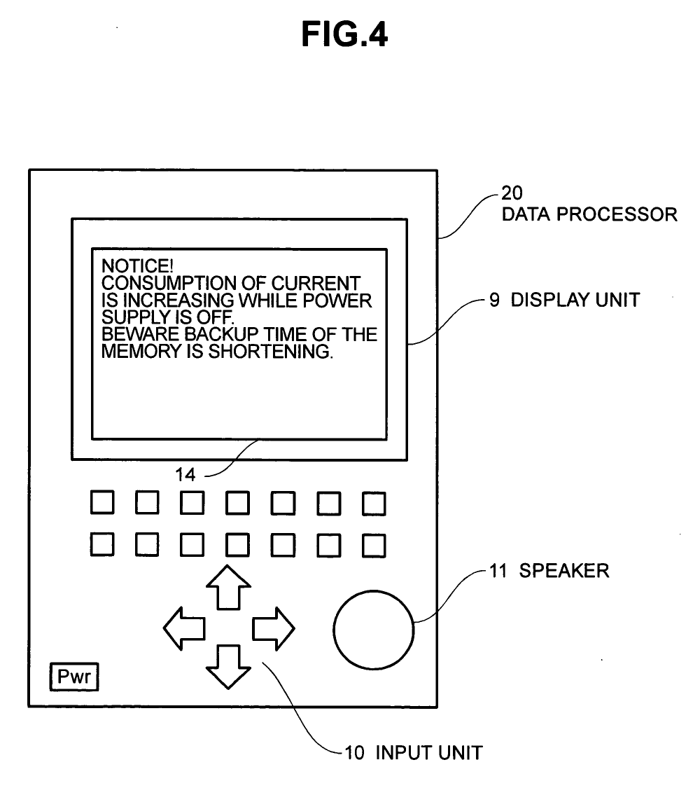

An external memory I/F (interface) 8 is a connection unit for connecting a memory card such as a compact flash (registered trademark) card or a SD card. The display unit 9 is constituted by a liquid crystal panel or the like, and displays characters, figures and/or images. An input unit 10 is a device by which the user inputs various data, and may include a power source button, various keys inclusive of function keys and numeral keys, or an input pen. There may be further provided a 4-way selection key as shown in FIG. 4. A speaker 11 produces a voice received via a communication unit 15, reproduced music sound of when there is an input of reproducing the music, and a message and alarm sound for the user. The communication unit 15 is a transceiver of a portable telephone communication unit, such as CDMA (code division multiple access) or TDMA (Time Division Multiple Access) system, an infrared ray communication unit, or a wireless LAN communication unit, and the unit 15 transmits and receives image data and voice data or the like.

External equipment I/F 12 is a connection unit for connection to other data processing equipment. A bus line 13 is a signal line for sending the data, address signals and control signals between the MPU 5 and the other devices such as display 9 and the like.

A battery 1 is a power source for supplying electric power to the data processor 20. A resistor 2 converts a current supplied from the battery into a voltage. An A/D converter 3 converts an analog voltage signal input from the resistor 2 into a digital signal. The resistor 2 and the A/D converter 3 form a current detector 16, in this example, although other types of current or power consumption detectors may be used. A DC/DC converter 4 converts the electric power supplied from the battery 1 into a DC voltage of an appropriate level, and supplies it to various devices in the data processor 20.

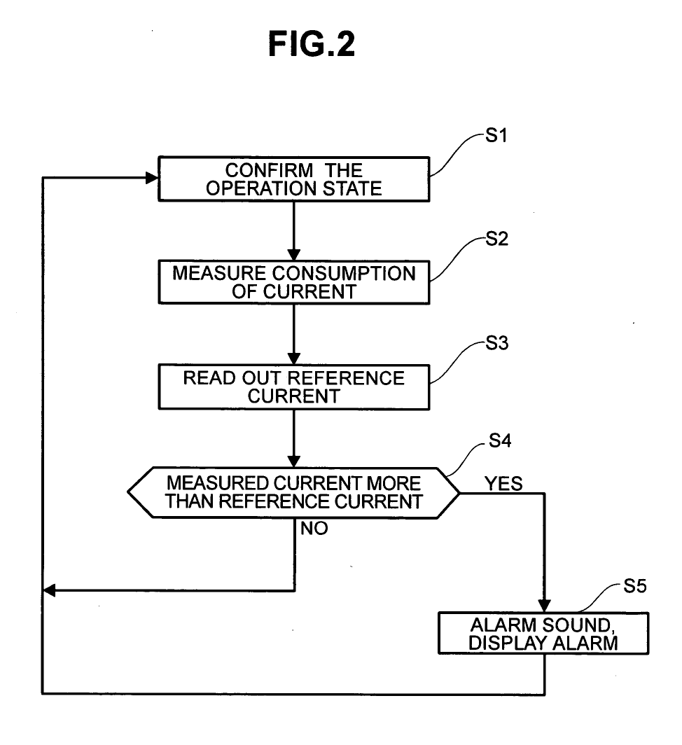

Next, a method of measuring the consumption of current of the battery 1, a method of comparing the currents and a method of providing pertinent information will be described with reference to FIG. 2. The method described below is controlled by the MPU 5 based on a program stored in the ROM 6.

First, the operation state of the data processor 20 is confirmed (S1). The operation state stands for, for example, a state displaying only the reception, such as, date, hour, remaining amount of the battery, electromagnetic wave condition, etc., a state where the dynamic image is being reproduced, and a state where the data are being written into the RAM 7.

After the operation condition is confirmed, the present consumption of current is measured (S2). In the example of FIG. 1, the MPU 5 of the processor reads the digital value from the detector 16. When the power source of the data processor 20 is on, the battery 1 supplies the electric power to the devices and, hence, a current I flows. The same current I also flows into the resistor 2, and a voltage E is generated across the resistor 2. At this moment, the resistance R of the current detecting resistor 2 is maintained constant. The current I may be calculated according to current I=voltage E/resistance R, hence, a value of current I may be represented by a value of voltage E. The A/D converter 3 receives the voltage E generated across the terminals of the resistor 2, and analog signals representing the level are converted into digital signals. The digital signals correspond to the data of current consumption, and is sent to the MPU 5 through the bus line 13.

When the current consumption data is input to the MPU 5, current data (reference value) for comparison corresponding to the operation state confirmed at S1 are read out from the database of currents for comparison stored in the ROM 6 (S3).

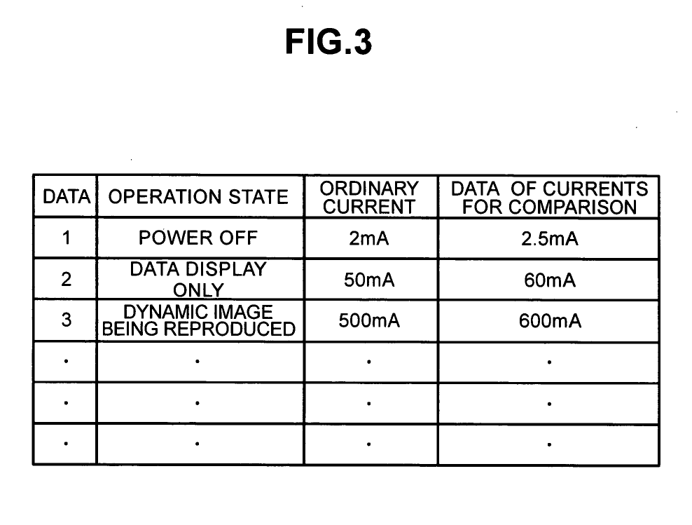

FIG. 3 shows an example of a database of currents for comparison. In the example of FIG. 3, the various operation states have corresponding values of ordinary current consumption and corresponding reference values for use in the current comparison. Here, the data of currents for comparison are set as the amounts of currents greater than the data of ordinary consumption currents by taking fluctuation in the data processor 20 into consideration. Here, the invention is in no way limited to the database shown in FIG. 3 only, but may omit the data of, for example, values of ordinary current consumption, or may store the data of ordinary consumption currents as the current data for comparison.

Next, the data of a current for comparison for the confirmed operation state is read out and compared with the data of a current consumption that is measured (S4). When the data of a measured current consumption is smaller than the data of a current value for comparison (S4, No), the routine returns back to S1. On the other hand, when the data of a measured current consumption is greater than the data of a current value for comparison (S4, Yes), the user is informed that the consumption current is in excess of an estimated value, for example, through the display 9 or the speaker 11 (S5).

FIG. 4 illustrates an example of a visual output on the display 9. The example of FIG. 4 is displaying an alarm 14, such as the consumption of current is increasing and the backup time of the memory is shortening. An alarm sound may be output from the speaker 11 together with the display of alarm 14. The user may not often be watching the display 9. By using the alarm sound from the speaker 11 in combination, therefore, the user is allowed to notice the display of alarm 14. Or, an alarm message may be output from the speaker 11 instead of displaying the alarm 14.

According to this example, the present consumption of current is detected and, when it is greater than the reference value, an alarm is displayed enabling the user to know that the data processor is consuming a current larger than an ordinary current for its present operation state and that the backup time of the memory and the processing time, such as application execution, are shortening.

In the example of FIG. 4, the user is notified that the consumption of current is increasing and the backup time of the memory is shortening. The invention, however, is in no way limited thereto only. For example, if the alarm that is displayed includes a message urging the user to electrically charge the battery, then, he may charge the battery earlier than when he would normally do it.

Further, when a memory card is connected to the external memory I/F 8, then, the display may be to urge the user to disconnect the memory card. The memory card that is connected could cause an increase in the consumption of current. Upon watching the above display, therefore, the user is urged to disconnect the memory card, and the increased consumption of electric power is suppressed.

Further, the consumption of electric power increases due to an increase of storage capacity and due to a program that is installed by the user. Therefore, a factor causing an increase in the consumption of electric power may be notified to the user. The MPU 5 stores, in the RAM 7, the storage capacity of the RAM 7 and the program name that is stored every time when the consumption of electric power is measured. The consumption of electric power that has become greater than the reference value, is then compared with the storage capacity of when the consumption of electric power was measured in the previous time and with the program name. Further, any program name that is newly added is notified to the user. Based on this notice, the user knows the factor that causes an increase in the consumption of electric power.

The processing shown in FIG. 2 may be executed when the power source is turned on or after every predetermined time interval, or may be executed for every dynamic image reproduction processing or every time when an instruction is input for starting the processing. However, the user may find it bothersome if the consumption of electric power is detected and notified every predetermined time interval or for every processing. Therefore, if the user is allowed to select the processing or the notice pattern, then, the notice can be issued depending upon the state of use chosen by the user, so that the user may find it easy to use.

FIGS. 1 and 2 illustrate an example only, however, the invention is in no way limited. In the example of FIG. 1, the resistor 2 is inserted in the negative terminal side of the battery 1 for measuring the consumption of current. However, the means for measuring the consumption of current is not limited thereto only but may use any other method if it is capable of measuring the consumption current without departing from the scope of the invention. In the example of FIG. 1, the detector 16 includes the resistor 2 and the A/D converter 3. However, the means for detecting the consumption of electric power is not limited thereto only but may use any other constitution. In addition to the constitution of FIG. 1, further, there may be provided a display unit for displaying, for example, alarm.

The order of processing of the flowchart shown in FIG. 2 is in no way limited thereto only, but the order of, for example, S1 and S2 may be replaced. Further, the program for executing the flowchart shown in FIG. 2 is not limited to being stored in the ROM 6 but may be such that the program is stored in the RAM 7. Upon being stored in the RAM 7, the user can try to upgrade to a new version to a program that is installed after having purchased the data processor 20, where the old version and/or the new version may implement the processing described herein.

The installed program is recorded on a machine-readable medium. The term “machine-readable medium” as used herein refers to any medium that participates in implementing the processing. Such a medium may take many forms, including but not limited to, non-volatile media, volatile media, and transmission media. Non-volatile media include, for example, optical or magnetic disks. Volatile media include dynamic memory. Transmission media may include coaxial cables; copper wire and fiber optics, as well as electric, electromagnetic or light signals that transmit such physical links Transmission media can also take the form of electric or electromagnetic signals, or acoustic or light waves such as those generated during radio frequency and infrared wireless data communications. Common forms of machine-readable media include, for example, a floppy disk, a flexible disk, hard disk, magnetic disk, magnetic tape, any other magnetic medium, a CD-ROM, DVD, any other optical medium, a RAM, a PROM, and EPROM, a FLASH-EPROM, any other memory chip or cartridge, a carrier wave transporting data or instructions.

The database of currents for comparison shown in FIG. 3 stores a current for each operation state. However, a plurality of conditions may be stored and may be selected by the user. For example, when the user uses the data processor in her/his office and the charging can be easily done, the data of a current for comparison is set to be high. When the user is in an environment where he cannot easily effect the charging, the data of a current for comparison is set to be low. Then, the alarm output depending upon a state of use by the user. Further, the database of currents for comparison may be stored in the RAM 7 and may be rewritten.

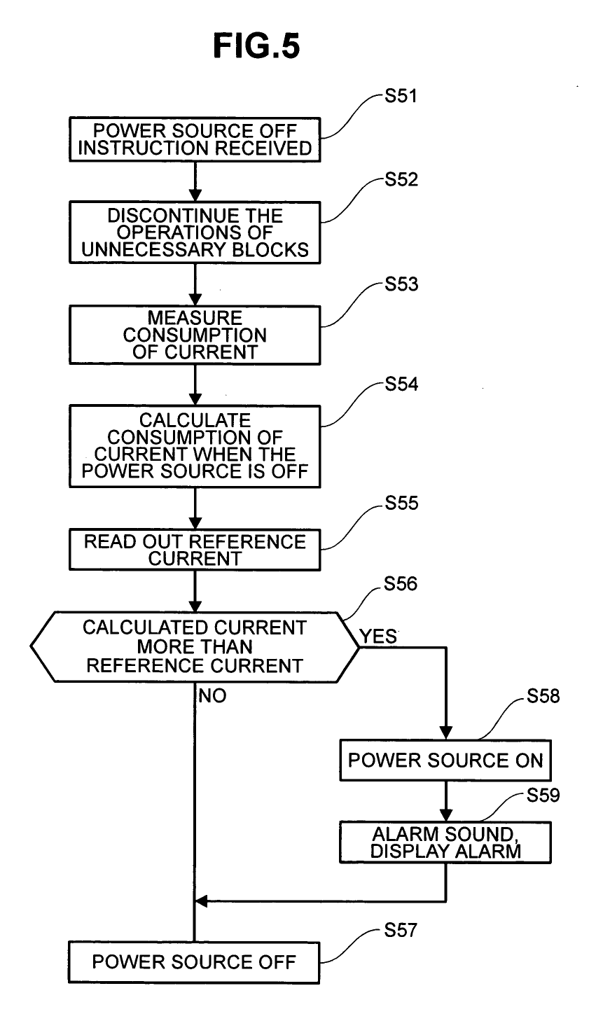

Next, described below are the method of measuring the consumption of current, method of comparing the currents and the method of informing the user when the user has turned the power source off, with reference to FIG. 5. The method described below is controlled by the MPU 5 based on a program stored in the ROM 6 or in the RAM 7.

When the power source off instruction is input from the input unit 10 (S51), the MPU 5 discontinues the operations of the blocks except the blocks necessary for measuring the consumption of current and for the comparison (S52). For example, the operations of the blocks such as display 9 and speaker 10, and the operations of unnecessary programs, are discontinued (power source off standby state).

Thereafter, the present consumption of electric power is measured in the same manner as at S2 in FIG. 2 (S53). Electric power is consumed by the circuitry for measuring a consumption value of current and the circuitry for comparing the measured current to the reference current. To determine and process a power-down consumption value, the consumption values for the measurement and the comparison functions are stored in advance in the ROM 6. To detect the consumption value in the power OFF state, a stored consumption value for the measurement and the comparison functions is subtracted from the measured consumption value at the time the user triggers turn-off.

A data of a current for comparison in a state where the power source is turned off is read out from the database of currents for comparison shown in FIG. 3 (S55), and a data of a calculated consumption current for a state where the power source is turned off is compared with the data of the corresponding current for comparison (S56). When the data of the calculated current is larger than the data of the current for comparison (S56, Yes), the power source of the display 9 or of the speaker 11 is turned on (S58), and the user is informed of the fact that the consumption of current is expected to be in excess of the value estimated, through the display 9 or the speaker 10 like at S5 of FIG. 2 (S59). Then, after the passage of a predetermined period of time, the power source of the A/D converter 3 and of the display 9 is turned off (S57). On the other hand, when the data of the current for comparison is larger than the data of the calculated consumption current (S56, No), the power source is turned off without displaying alarm (S57).

The current may often increase when the power source is being turned off due to an increase in the backup current as a result of increasing the memory, due to occurrence of a leakage current caused by the connection to an external equipment, and due to the turn on of a circuit that should have been turned off since a new program was installed. In the state where the power source is off, the consumption of current is small. Therefore, a great effect appears due to an increase in the current. When, for example, the backup current of the extension memory is 2 mA, then, a current of 4 mA flows though the flow of current should have been 2 mA and, hence, the duration time becomes one-half the time that was expected first. The user without knowing an increase in the consumption of current in the OFF state may leave the data processor to stand while turning the power source off in a traditional manner. In that case, it could happen that the battery has been depleted when he tries to turn the power source on again in a customary manner. Here, if the DRAM is used for the data processor, it could happen that the data input by the user are erased.

In this example, when the user turns the power source off, the consumption of current becomes larger than that during the normal state with the data processor being turned off, which can be utilized for letting the user know that the backup time of the memory is shortening.

Further, the data processor may be constituted as described above.

The data base of schedule is stored in the RAM 7, a step for confirming the schedule data is added to the flowchart of FIG. 2 or 5, an increase in the consumption of current is detected, and the state of use by the user is confirmed. When a schedule of going out, such as business trip, within, for example, 24 hours, is written into the schedule data while the consumption of electric power is increasing, a message is output, such as “Please charge since you are going to take a business trip”, “Consumption of power is increasing. Carry a charger with you when you go to a business trip”.

This prevents such an occurrence that the data processor suddenly becomes out of operation due to the depleted battery or that important data are erased. Upon including the schedule data such as a schedule of going out in the message, the user is allowed to confirm the schedule without the need to access the database of schedule.

When the power source is turned off before the holidays or before a rest day such as Friday, the message may request the charging and may further request to disconnect the memory card and the external equipment. Upon urging the user to disconnect the memory card, it is made possible to decrease the consumption of electric power during the turn off of power source.

Or, the message may state the necessity of charging prior to going out or prior to taking holidays irrespective of an increase in the consumption of current. This urges the user to effect the charging, and prevents the occurrence of such problems that the data processor cannot be used due to the depletion of the battery while going out or after the holidays and that the data are erased. Further, whether the data processor will be used for the business or for a private purpose, is selectively registered, and the conditions for notifying the message are varied depending upon the use, enabling the remaining amount of the battery and the necessity of charging to be notified to the user.

This example provides a data processor that can be favorably used by the users.

What is claimed is:

1. A data processor having a battery, comprising:
a memory for storing data on electric power consumption in advance;
a detector which detects a electric power supplied from the battery to the data processor; and
a message output which provides an indication when the electric power detected by the detector is greater than the consumption data stored in the memory.

2. A data processor having a battery, comprising:
a memory for storing data on current in advance;
a current detector which detects current supplied from the battery to the data processor; and
a controller which provides notification when the current detected by the current detector is greater than the current data stored in the memory.

3. The data processor according to claim 2, wherein the memory stores a plurality of data on current, the controller reads out one of the plurality of data depending upon condition of the data processor and compares the data read from memory with the current detected by the current detector.

4. The data processor according to claim 2, further comprising:
a power source button which receives an instruction for turning on/off power to the data processor;
wherein the current detector detects current when the power source button is pressed by a user.

5. The data processor according to claim 2, further comprising:
a input key which receives an instruction for turning on/off a power to the data processor;
wherein the controller turns off part of the data processor when the input key has received an instruction for turning off power to the data processor, and the current detector detects current after the power consumption in part of the data processor is turned off.

6. The data processor according to claim 2, wherein the current detector detects current at predetermined time intervals.

7. The data processor according to claim 2, further comprising:
a connector for connecting a memory card;
wherein the controller provides a message urging the user to disconnect the memory card from the connector when the current detected by the current detector is larger than the current data stored in the memory.

8. A data processor having a battery, comprising:
a memory for storing data on current;
a current detector which detects current supplied from the battery to the data processor; and
a controller which provides notice that the battery should be charged when the current detected by the current detector is greater than the current data stored in the memory.

9. A data processor having a battery, comprising:
a memory for storing data on electric power consumption
a detector which detects a electric power supplied from the battery to the data processor; and
a controller which provides notice that the battery should be charged when the electric power detected by the detector is greater than the data stored in the memory.

10. The data processor according to claim 8, wherein the memory stores schedule data, and the controller provides notice that the battery should be charged depending upon the schedule data, even when the current detected by the current detector is smaller than the current data stored in the memory.

11. The data processor according to claim 9, wherein the memory stores schedule data, and the controller also provides notice that the battery should be charged depending upon the schedule, data even when the electric power detected by the detector is smaller than the data stored in the memory.

12. A data processor having a battery, comprising:
a memory which stores data on a schedule of the data processor's user;
a power source button which receives an instruction for turning on/off power to the data processor; and
a message output which provides a message indicating the suggestion of electrically charging the battery depending upon the data stored in the memory when the power source button is pressed by a user.

13. The data processor according to claim 12, wherein the output provides the message when the power source button is pressed before a holiday or a weekend.

14. The data processor according to claim 13, wherein the message includes a suggestion for disconnecting an external equipment from the data processor.

15. A method for notification comprising the steps of:
storing data on electric power consumption or electric current in a memory of a data processor;
detecting electric power or electric current supplied from a battery of the data processor;
reading out a value of the data from the memory; and
outputting an indication when the detected electric power or electric current supplied from the battery is greater than the data value read out from the memory.

16. A method for notification comprising the steps of:
storing a schedule of a data processor's user;
reading out the schedule in response to an instruction for turning on/off power to the data processor; and
outputting a message indicating the suggestion of electrically charging a battery of the data processor depending upon the schedule data.

17. A software product comprising:
at least one machine readable medium;
a database carried on the at least one machine readable medium and readable therefrom by a data processor,
the database containing data on electric power consumption or electric current; and
programming code, carried by the at least one machine readable medium, for execution by the data processor, wherein execution of the programming code causes the data processor to implement a series of steps, comprising:
detecting electric power or electric current supplied from a battery of the at least one programmable processor;
reading out a value of the data from the database; and
outputting an indication when the detected electric power or electric current supplied from the battery is greater than the data value read out from the database.

18. A software product comprising:
at least one machine readable medium;
a database carried on the at least one machine readable medium and readable therefrom by a data processor, the database containing a schedule of the data processor's user; and
programming code, carried by the at least one machine readable medium, for execution by the data processor, wherein execution of the programming code causes the data processor to implement a series of steps, comprising:
reading out the schedule in response to an instruction for turning on/off power to the data processor; and
outputting a message indicating the suggestion of electrically charging a battery of the data processor depending upon the schedule data.
